(19) United States
(12) Patent Application Publication
(10) Pub. No.: US 2008/0218034 A1
(43) Pub. Date: Sep. 11, 2008

(54) Piezo Actuator and Method For The Production Thereof

(76) Inventor: Frank Mai, Eberdingen (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 11/914,670

(22) PCT Filed: Jul. 5, 2006
(86) PCT No.: PCT/EP06/63921

§ 371 Date: Nov. 16, 2007

(30) Foreign Application Priority Data
Jul. 5, 2005 (DE) 10 2005 031 3426

(51) Int. Cl. H01L 41/047; B28B 1/48; H01L 41/24

(52) U.S. Cl. 310/364; 264/678; 29/25.35; 310/365

(57) ABSTRACT

The invention is a method for producing a piezo actuator starting with the assembly of a plurality of actuator layers made of a ceramic material and a plurality of metallic layer electrodes disposed between the actuator layers to form a green member. The metallic layer electrodes are alternately electrically connected a respective terminal electrode via which a voltage can be applied to the layer electrodes. The terminal electrode extends within the piezo actuator through respective longitudinal bores. The piezo actuator has an end face and an opposing base. According to the inventive production method, the terminal electrode protrudes from the end face of the green member. The green member is heated until the sintering process has been completed, during which the end of the terminal electrode that protrudes from the end face is supported such that the green member is not deformed during the sintering process. A piezo actuator produced according to the method encompasses at least one terminal electrode which is configured in a tubular manner and extends inside the piezo actuator.

The invention relates to a piezo actuator, which is preferably used as a final control element, and to a method for producing this piezo actuator.

### PRIOR ART

Piezo actuators are used in many areas in fuel injection, for instance as a final control element or for actuating a nozzle needle, especially in diesel injection systems. The actuator must make a minimal force and a minimal stroke available so that the corresponding final control element that is to be moved by the piezo actuator will function properly. Usually, piezo actuators constructed as so-called multilayer actuators are used. These comprise a plurality of ceramic layers that typically have a layer thickness of approximately 100 μm. Layer electrodes are disposed in alternating fashion between the ceramic layers and are contacted to terminal electrodes in alternation. By the application of an electrical voltage between the terminal electrodes, an electrical field is produced between each two adjacent layer electrodes, so that the ceramic layer located between the two layer electrodes changes thickness, depending on the magnitude of the electrical field.

The force of the piezo actuator is determined by the active cross-sectional area, that is, the area through which the applied electrical field penetrates. The stroke is in turn determined by the relative elongation of the piezoelectric ceramic upon application of the electrical field. Care should be taken to assure that exceeding a maximum electrical field intensity is precluded, since otherwise disruptive breakdowns would occur between the individual layer electrodes, which would lead to a short circuit and hence to failure of the component. Hence with a maximum electrical field, increasing the stroke is possible only by means of a higher number of ceramic layers and hence with a longer piezo actuator.

For contacting the layer electrodes, various terminal electrodes are known from the prior art. German Patent Disclosure DE 199 132 71 A1, for instance, shows a piezo actuator which has two terminal electrodes applied to the outer face of the piezo actuator, and the layer electrodes are brought in alternation to the surface of the piezo actuator. At these terminal electrodes located on the outside, a suitable electrical voltage can be applied to the layer electrodes. Furthermore, for instance from German Patent Disclosure DE 103 350 19 A1, terminal electrodes are known that extend in the interior of the piezo actuator. In that case, two longitudinal bores are made in the piezo actuator, and rodlike terminal electrodes are introduced that each contact the layer electrodes in alternation in the interior of the piezo actuator. As a result, the structural space of the piezo actuator is reduced, and the terminal electrodes are protected in the interior of the piezo actuator.

Because of the installation conditions that prevail for instance in a piezoelectric injector that is used for direct-injection diesel engines, the maximum cross-sectional area of the piezo actuator is limited, and thus the attainable maximum force is equally limited. To increase the maximum stroke, the number of ceramic layers can be increased, but this is limited by the production process: The piezo actuators are made from a green body and sintered in free-standing fashion in the furnace. If the piezo actuator becomes too long in proportion to the base, however, there is the danger that the piezo actuator will warp during sintering and thus be fixed in a skewed position, which makes the piezo actuator unusable. Bracing the piezo actuator with a guide, however, is hardly possible, since on the one hand there is the danger that material from the bracing device will diffuse into the actuator and cause defects to be incorporated into the piezoelectric ceramic. On the other hand, a static bracing device is not possible, since because of the sintering process the actuator shrinks, and the bracing device would thus have to be tracked. In the final analysis, this means that in piezo actuators, a certain length-to-width ratio cannot be exceeded.

### ADVANTAGES OF THE INVENTION

By means of the method according to the invention for producing a piezo actuator, it is possible to produce even very long piezo actuators in a single sintering process. To that end, for internal contacting, a longitudinal bore is made in the green body that forms the piezo actuator after the sintering. A tubular terminal electrode is introduced into the longitudinal bore, and the terminal electrode protrudes past one of the face ends of the green body. The protruding end of the terminal electrode is now braced in such a way that the green body cannot become warped during the sintering process.

The method for producing the piezo actuator can be further developed by further advantageous method steps. Thus during the sintering process, the green body can rest on its base, which is diametrically opposite the protruding end of the terminal electrode. It is equally possible for the green body to be suspended from the protruding terminal electrode during the sintering process. It is especially advantageous if one of the terminal electrodes extends precisely symmetrically in the middle of the green body, so that no tilting moments on the green body which could promote warping during the sintering process are brought about.

It is also possible for a guide pin to be introduced into the terminal electrodes during the sintering process, which leads to further stabilization. Especially if the terminal electrodes are made from copper, they soften because of the high temperatures during the sintering process, so that further stabilization by a guide pin, which is preferably made from ceramic or a metal with a high melting point, leads to an improvement of the process.

It is also advantageous if the tubular terminal electrode is solidly connected to the wall of the longitudinal bore in the sintering process, so that a solid connection is brought about between the terminal electrode and the layer electrodes.

Thus by means of the method of the invention, a piezo actuator is made available which is distinguished in that the terminal electrodes that extend in the interior of the piezo actuator are embodied as thin metal tubes that are sintered into the longitudinal bore of the piezo actuator. These tubular terminal electrodes can then be filled for instance with an electrically conductive or nonconductive material, which lends the piezo actuator additional stability.

### DRAWING

A piezo actuator of the invention is shown in the drawing.

FIG. 1 shows a piezo actuator of the invention in a side view, with a guide for the terminal electrodes during the sintering process; and

FIG. 2 shows a longitudinal section through a piezo actuator or green body according to the invention.

### DESCRIPTION OF THE EXEMPLARY EMBODIMENT

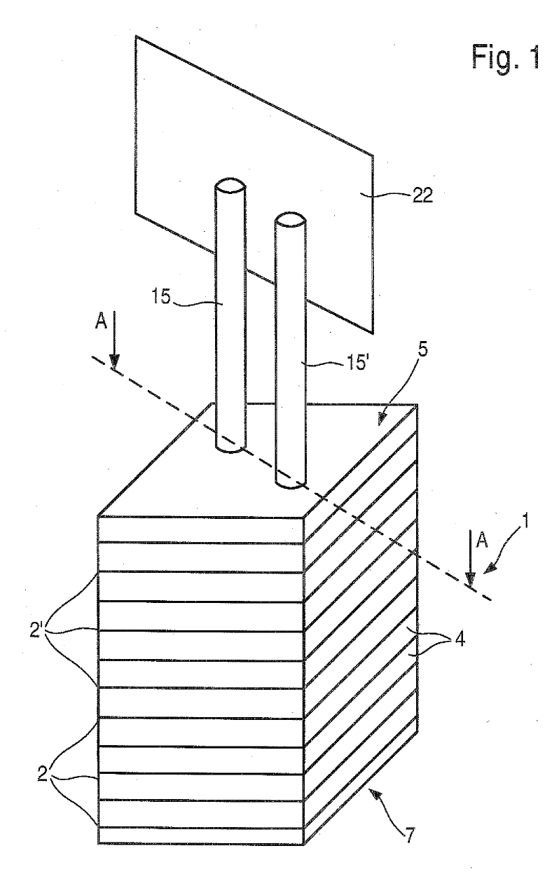

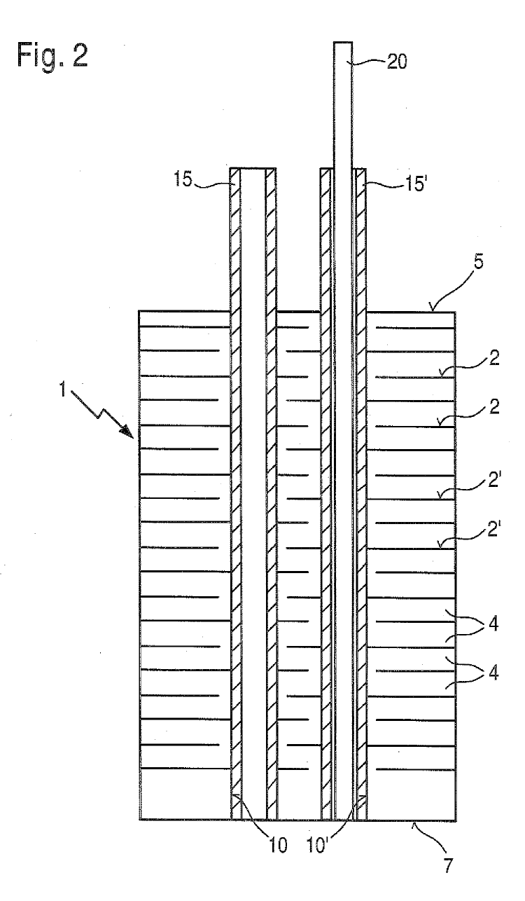

In FIG. 1, a piezo actuator of the invention is shown in a side view. FIG. 2 shows the same piezo actuator in a longitudinal section taken along the plane marked A-A in FIG. 1. The piezo actuator 1 has an end face 5 and a diametrically opposed base 7 and comprises a plurality of actuator layers 4, which all have at least approximately the same layer thickness and which are oriented parallel to one another. The actuator layers 4 comprise a ceramic piezoactive material, which before the sintering process is in the form of a green sheet. Various layers of this green sheet are stacked one above the other, until a green body of the desired height is attained. Between each two actuator layers 4, there is one layer electrode 2, 2′, which comprises a metal that is a good electrical conductor, such as silver or a silver alloy. As FIG. 2 shows, alternating layer electrodes 2, 2′ have a recess through which two longitudinal bores 10, 10′, which extend in the actuator body 1, pass. As a result, only the layer electrodes 2 show at the wall of the longitudinal bore 10, while at the wall of the longitudinal bore 10′, the layer electrodes 2′ are visible.

FIG. 2 shows the piezo actuator 1 as a green body, or in other words before the sintering process. A tubular terminal electrode 15, 15′ is inserted into each of the longitudinal bores 10, 10′, so that the terminal electrode 15, 15′ extends over the entire length of the piezo actuator 1. The tubular terminal electrode 15, 15′ is embodied here as a thin copper tubule, for example, but some other metal material may also be used. The tubular terminal electrodes 15, 15′ have a diameter that is somewhat smaller than the diameter of the longitudinal bore 10, 10′, and thus the terminal electrodes 15, 15′ on the one hand can be introduced more easily, and on the other, the shrinkage of the green body in the sintering process is taken into account.

The production process now takes place, in that the green body as shown in FIG. 2, is put into a suitable sintering furnace. The tubular terminal electrodes 15, 15′ rest here on a guide 22, for instance, which assures that the terminal electrodes 15, 15′ are only very limitedly movable. For further stabilization of the tubular terminal electrodes 15, 15′, a guide pin 20 can also be inserted into the interior of the terminal electrodes 15, 15′, in which case care must be taken to assure that it likewise has some play in the interior of the terminal electrode 15, 15′. During the sintering process, the green body heats up; filler material evaporates, and a hard ceramic body is formed. The green body shrinks in the process, and the individual actuator layers 4 become solidly joined both to the layer electrodes 2, 2′ and to one another.

Because of the process of shrinkage of the green body, the diameter of the longitudinal bores 10, 10′ also decreases, to such an extent that the tubular terminal electrodes 15 are firmly clamped in place in the longitudinal bore 10, 10′. Care must be taken here to assure that the terminal electrodes 15, 15′ not have too great an outer diameter, since otherwise overly high mechanical stresses would occur in this region. As a result of the shrinkage of the green body, the terminal electrodes 15, 15′ are pressed firmly against the respective layer electrodes 2, 2′ that emerge at the wall of the respective longitudinal bore 10, 10′. Thus after the sintering process, the terminal electrode 15 contacts the layer electrodes 2, while the terminal electrode 15′ contacts the layer electrodes 2′. The guide pin 20 may either remain in the terminal electrode 15, 15′ and embodied such that it is firmly clamped in the terminal electrode 15, 15′, or it may also be provided that the diameter of the guide pin 20 be selected such that it can be removed again afterward. The end of the terminal electrodes 15, 15′ that protrudes past the end face 5 of the piezo actuator 1 can be cut off after the sintering process, so that the piezo actuator 1 can be installed in the known manner. To facilitate the removal of the guide pin 20, it may also be provided that it be inserted into the terminal electrode 15, 15′ only so far that one end extends up to the height of the end face 5. This assures that after the protruding terminal electrodes 15, 15′ have been cut off, the guide pin 20 is removed as well.

It may also be provided that the piezo actuator 1 or green body not rest on the base 7 during the sintering process, but instead is suspended from one or both terminal electrodes 15, 15′. It is advantageous in particular if one of the terminal electrodes 15, 15′ extends centrally in the piezo actuator 1, so that no tilting moment on the green body ensues. It may also be provided that the protruding end of the terminal electrodes 15, 15′ are not cut off completely after the sintering process, so that the protruding ends can be used for contacting connection lines.

1-12. (canceled)

13. A method for producing a piezo actuator having an end face and a base diametrically opposite the end face, the actuator having a plurality of actuator layers of a ceramic material and a plurality of metal layer electrodes disposed between the actuator layers to form a boby of the piezo actuator, the metal layer electrodes being connected electrically in alternation each to a respective terminal electrode, through which an electrical voltage can be applied between the individual layer electrodes, and at least one terminal electrode extending through the body of the piezo actuator, said method steps comprising:
making at least one longitudinal bore in a body that forms the piezo actuator;
introducing a terminal electrode into the longitudinal bore, with the terminal electrode protruding past the face end of the body;
heating the body until the sintering process is concluded, and the end of the terminal electrode that protrudes past the end face is braced such that the green body does not warp during the sintering process

14. The method as defined by claim 13, characterized in that the terminal electrodes are embodied in tubular form.

15. The method as defined by claim 13, characterized in that during the sintering process, the green body stands on the base diametrically opposed to the protruding end of the terminal electrode.

16. The method as defined by claim 13, characterized in that during the sintering process, the green body is suspended from the terminal electrode.

17. The method as defined by claim 13, characterized in that during the sintering process, a guide pin is inserted into the tubular terminal electrode, so that the terminal electrode is guided on the guide pin.

18. The method as defined by claim 14, characterized in that during the sintering process, a guide pin is inserted into the tubular terminal electrode, so that the terminal electrode is guided on the guide pin.

19. The method as defined by claim 16, characterized in that the guide pin is made from ceramic or a metal with a high melting point.

20. The method as defined by claim 13, characterized in that the terminal electrode has a play in the longitudinal bore such that after the sintering process, it is firmly clamped by the wall of the longitudinal bore of the piezo actuator.

21. The method as defined by claim 13, characterized in that after the sintering process, the end of the terminal electrode protruding past the face end of the piezo actuator is cut off.

22. The method as defined by claim 13, characterized in that the tubular terminal electrode is made from copper.

23. The method as defined by claim 14, characterized in that the tubular terminal electrode is made from copper.

24. The method as defined by claim 15, characterized in that the tubular terminal electrode is made from copper.

25. The method as defined by claim 16, characterized in that the tubular terminal electrode is made from copper.

26. The method as defined by claim 17, characterized in that the tubular terminal electrode is made from copper.

27. The method as defined by claim 20, characterized in that the tubular terminal electrode is made from copper.

28. The method as defined by claim 21, characterized in that the tubular terminal electrode is made from copper.

29. A piezo actuator having a plurality of actuator layers of a ceramic material and having a metal layer electrode, each disposed between respective actuator layers, which layer electrodes are connected electrically in alternation to a respective terminal electrode, by way of which terminal electrode an electrical voltage can be applied to the layer electrodes, and at least one of the terminal electrodes extends inside the piezo actuator, characterized in that at least one terminal electrode is embodied as a metal, tubular terminal electrode, which is sintered in a longitudinal bore of the piezo actuator.

30. The piezo actuator as defined by claim 29, characterized in that the interior of the tubular terminal electrode is filled with an electrically nonconductive material.

31. The piezo actuator as defined by claim 29, characterized in that the metal, tubular terminal electrode is made from copper.

32. The piezo actuator as defined by claim 30, characterized in that the metal, tubular terminal electrode is made from copper.
